(19) United States
(12) Patent Application Publication
(10) Pub. No.: US 2024/0045723 A1
(43) Pub. Date: Feb. 8, 2024

(54) HIERARCHICAL COMPUTE AND STORAGE ARCHITECTURE FOR ARTIFICIAL INTELLIGENCE APPLICATION

(71) Applicant: Intel Corporation, Santa Clara, CA (US)

(72) Inventors: Deepak Dasalukunte, Beaverton, OR (US); Richard Dorrance, Hillsboro, OR (US); Renzhi Liu, Portland, OR (US); Henchen Wang, Portland, OR (US); Brent Carlton, Portland, OR (US)

(21) Appl. No.: 18/477,816

(22) Filed: Sep. 29, 2023

(51) Int. Cl. G06F 9/50; G11C 7/10

(52) U.S. Cl. CPC G06F 9/5033; G06F 9/5016; G11C 7/1012

(57) ABSTRACT

Systems, apparatuses and methods include technology that executes, with a compute-in-memory (CiM) element, first computations based on first data associated with a workload, and a storage of the first data, executes, with a compute-near memory (CnM) element, second computations based on second data associated with the workload and executes, with a compute-outside-of-memory (CoM) element, third computations based on third data associated with the workload. The technology further receives, with a multiplexer, processed data from a first element of the CiM element, the CnM element and the CoM element, and provides, with the multiplexer, the processed data to a second element of the CiM element, the CnM element and the CoM element.

### TECHNICAL FIELD

Examples generally relate to a system level compute and memory architecture that may integrate different technologies and/or different variations of the hardware architectures. In particular, examples include a hierarchy of closely connected circuits (e.g., compute-in-memory (CiM), compute-near-memory (CnM) and compute-outside-of-memory (CoM)) to process and store data to execute computations.

### BACKGROUND

Machine learning (e.g., neural networks, deep neural networks, etc.) workloads may include a significant amount of operations. For example, machine learning workloads may include numerous nodes that each execute different operations. Such operations may include General Matrix Multiply operations, multiply-accumulate operations, etc. The operations may consume memory and processing resources to execute, and occur in different data formats.

### BRIEF DESCRIPTION OF THE DRAWINGS

The various advantages of the embodiments will become apparent to one skilled in the art by reading the following specification and appended claims, and by referencing the following drawings, in which:

FIG. 1 is an example of a compute and memory architecture according to an embodiment;

FIG. 2 is a flowchart of an example of a method of executing a hierarchical compute and storage according to an embodiment;

FIG. 3 is an example of a diagram of different arrangements of CiM, CnM and CoM according to an embodiment;

FIG. 4 is an example of a central processing unit memory hierarchy according to an embodiment;

FIG. 5 is an example of a CiM prefetch process according to an embodiment;

FIG. 6 is an example of a CiM operation process according to an embodiment;

FIG. 7 is an example of a CiM DAC load process according to an embodiment;

FIG. 8 is an example of a CiM partial load process according to an embodiment;

FIG. 9 is an example of a CiM addition and accumulation according to an embodiment;

FIG. 10 is an example of a CiM memory storage process according to an embodiment;

FIG. 11 is an example of a memory storage architecture according to an embodiment;

FIG. 12 is a diagram of an example of a computation enhanced computing system according to an embodiment;

FIG. 13 is an illustration of an example of a semiconductor apparatus according to an embodiment;

FIG. 14 is a block diagram of an example of a processor according to an embodiment; and

FIG. 15 is a block diagram of an example of a multi-processor based computing system according to an embodiment.

### DESCRIPTION OF EMBODIMENTS

CiM elements (e.g., circuitry) may accelerate artificial intelligence (AI) and/or machine learning (ML) applications and compute by avoiding and/or mitigating memory bottlenecks. CiM accelerators may achieve efficiency due to considerable reduction in data movements between the memory and the compute units. CiM architectures may seek to achieve lower power, resolve memory bottlenecks and/or implement AI in battery operated and/or power-constrained devices. Existing CiM architectures may include analog based cores using static random-access memories (SRAMs) or other memory technologies such as magnetoresistive random-access memories (MRAMs), resistive random-access memories (RRAMs) etc. CiM architectures may be homogenous in nature. That is, CiM architectures may be analog-based pure compute-in-memory, while in examples of digital-based compute near memory, logic is positioned very close to the memory. Previously existing implementations may not integrate various levels of CiM architectures resulting inefficiency.

Digital architectures may include CnM architectures, where the compute units of the CnM are positioned proximate to the memory. Thus, CiM architectures may operate in an analog domain and perform a first set of functions, while CnM architectures may operate in a digital domain and perform a second set of functions distinct from the first set of functions. The second set of functions may be arithmetic (e.g., multiplication, addition, subtraction, division, etc.) operations.

Examples provide a system level enhancement that integrates both analog and digital technologies and/or different variations of the hardware architecture to further enhance and leverage CiM technology and CnM technologies. Examples include a unified weight storage and computation at leaf node compute units (e.g., CiM elements) to reduce and/or avoid memory bandwidth issues associated with moving weights from a centralized storage location. Examples provide enhancements to benefit small (e.g., low power) inference nodes that may reduce a reliance on traditional von Neumann approach of compute. Examples further provide energy reduction, processing acceleration and/or efficiency relative to existing central processing unit (CPU) memory hierarchies. For example, the examples may provide a significant increase in speed of computations and executions of workloads in performance based on the number formats.

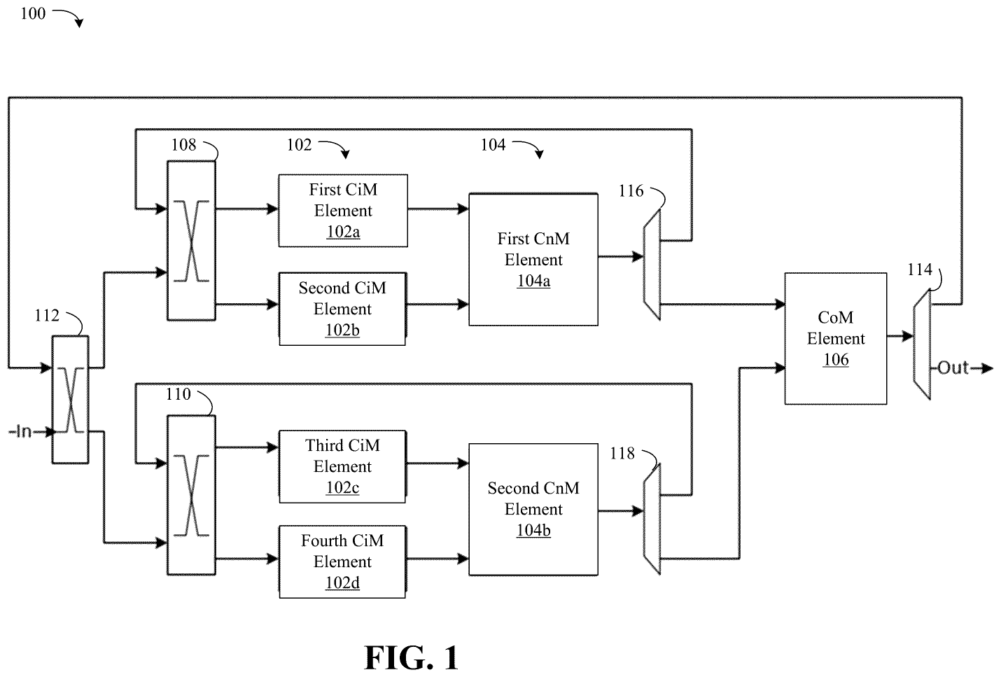

Turning now to FIG. 1, a compute and memory architecture 100 is shown. The compute and memory architecture 100 may executing AI learning, machine learning, AI inference and machine learning inference. The compute and memory architecture 100 includes a multi-level hierarchy for processing and computations with compute elements at various levels of in-memory-compute.

The compute and memory architecture 100 may be categorized into a CiM layer 102, a CnM layer 104 and a CoM element 106. The CiM layer 102, the CnM layer 104 and the CoM element 106 may be connected to each other through different connections and electrical components.

The CiM layer 102 may comprise first-fourth CIM elements 102a-102d. The first-fourth CIM elements 102a-102d may be positioned within a memory array(s) (e.g., SRAM array(s)). The memory array(s) may be extremely dense and execute a simple compute (e.g., multiply-accumulate (MAC)).

The CnM layer 104 includes first and second CnMs 104a, 104b. The first and second CnMs 104a, 104b are positioned proximate to and in the periphery of the memory arrays of the CiM elements 102a-102d. The CnM layer 104 executes high density compute that is slightly more complex compute than first-fourth CiMs 102a-102ds (e.g, MAC, absolute value, rectified linear unit (ReLU) activation functions, etc.).

The CoM 106 element is a more complex compute. The CoM element 106 may be similar to an arithmetic logic unit (ALU) or floating-point unit (FPU). The CoM element 106 may be considered a lower density compute, and is extremely configurable and flexible. In some examples, the CoM element 106 may be a processor (e.g., CPU, host processor, graphics processing unit, vision processing unit, accelerator, etc.).

The CiM layer 102 may be considered the lowest level of the multi-level hierarchy. The CiM layer 102 may include first-fourth CiM elements 102a, 102b, 102c, 102d (e.g., cores and/or tiles, circuitry that includes memory and processing elements). The first-fourth CiM elements 102a-102d may operate in the analog domain to execute analog compute that is built within a memory, for example an SRAM or cache. The CiM layer 102 may include a C-2C ladder to execute analog computations (e.g., first computations such as MAC operations).

The CnM layer 104 includes first and second CnM elements 104a, 104b that execute second computations (e.g., be accumulation, multiplication, absolute value, bias addition, or a ReLU (rectified linear unit) activation function for AI/ML applications, etc.). The CnM layer 104 may be at a level higher than CiM layer 102. Each of the first and second CnM elements 104a, 104b (e.g., cores, circuitry, advance processing elements, etc.) is associated with a group of the first-fourth CiM elements 102a-102d. For example, the first CnM element 104a is directly connected with first and second CiM elements 102a, 102b to receive data from the first and second CiM elements 102a, 102b. The second CnM element 104b is directly connected with the third and fourth CiM elements 102c, 102d to receive data from the third and fourth CiM elements 102c, 102d.

The first and second CnM elements 104a, 104b perform the next level of computation and/or execute when outputs are to be computed across multiple CiM elements of the first-fourth CiMs 102a-102d. For example, the first CiM element 102a and the second CiM element 102b may process different data, and provide respective first and second outputs to the first CnM element 104a. The first CnM element 104a may execute an operation based on the first and second outputs to generate a third output. The third output may be provided to the first CiM element 102a and/or the second CiM element 102b for storage and/or further processing, and/or provided to the CoM element 106 for further processing.

In some examples, the first-fourth CiM elements 102a-102d may also operate as a CiM cache (e.g., L2 cache, discussed below) as a part of a processor architecture. Thus, from the perspective of the first and second CnM elements 104a, 104b, the first-fourth CiM elements 102a-102d may be accessed and operated as an existing memory, and the first and second CnM elements 104a, 104b may read the values from the first-fourth CiM elements 102a-102d treating the first-fourth CiM elements 102a-102d as a memory. The first and second CnM elements 104a, 104b may request data from the first-fourth CiM elements 102a-102d with an instruction set supported by the first-fourth CiM elements 102a-102d.

For example, a read operations at the first and second elements CnM elements 104a, 104b may be executed with the pseudo-code I below. Pseudo-code I illustrates two types of instructions: (1) for fetching the data from the memory, and (2) fetching the data from one of the CiM elements with an operation performed enroute.
CnM=read (CiM, location)
CnM=read (CiM, location, operation)

### Pseudo-Code I: CnM Read Instructions

Compute operations at the first and second CnM elements 104a, 104b are further executed. The CnM level instructions, in addition to the data fetch instruction described above in Pseudo-code I, may comprise compute instructions. The compute instructions may operate on data that is explicitly read from one or more CiM elements of the first-fourth CiM elements 102a-102d and treats the one or more CiM elements as a traditional memory. Some examples may read out from the first-fourth CiM elements 102a-102d with an implied instructions at the CiM level or a mix of the explicit reading and the implied instruction described above. An example Pseudo-code II is shown below:
a=read (CiM, location)
b=read (CiM, location, operation)
c=compute(a, b)

### Pseudo-Code II: CnM Instructions

In pseudocode II, “a” is a value read from a CiM location of the first-fourth CiM elements 102a-102d. “b” is read from a computation CiM of the first-fourth CiM elements 102a-102d, and when the computation CiM executes an operation before data “b” of the computation reaches a corresponding one of the first and second CnM elements 104a, 104b that will further process data “b.” Finally, the compute instruction, which is executed by one of the first and second CnM elements 104a, 104b operates upon a and b to produce output c. Thus, in some examples the one of the first-fourth CiM elements 102a-102d stores data (e.g., second data), and one of the first and second CnM elements 104a, 104b fetches and/or reads the data from the one of the first-fourth CiM elements 102a-102d to execute an operation on the data.

The CoM element 106 may be a third arithmetic element (e.g., unit) at a level higher than the CnM layer 104 in the hierarchy. The CoM element 106 (e.g., an ALU and/or FPU, etc.) may execute third computations (e.g., complex functions like exponents, trigonometric functions, square roots, etc.). The CoM element 106 may include arithmetic and/or a CPU controlling (e.g., overseeing) a larger set of CnM tiles or instances, such as the CnM layer 104. The CoM element 106 may be denoted as an arithmetic element (unit) and/or a CPU. The CoM element 106 (may include more than one CoM element) or instances may be similar to CPU cores and may also be application specific accelerator units comprising dedicated instructions. The commonality of instruction types carries forward from CiM and CnM instructions. Pseudo-code III below exemplifies the capabilities of the CoM element 106.
1. a=read (respective CnM, location)
2. b=read (respective CnM, location, read (CiM, location, operation))
3. c=compute1 (a, b)

### Pseudo-Code III: Arithmetic/CoM Element 106 Instructions Performing Hierarchical Operations (Via CnM Layer 104 and CiM Layer 102)

In the first instruction (line one), the CoM element 106 is accessing a respective CnM location of the first and second CnM elements 104a, 104b, while in the second instruction (line two), the read instruction is accessing a respective location of the first and second CnM elements 104a, 104b which is in turn calling a CiM instruction over which an operation is performed.

In this example and in the second instruction, the respective data from a respective CiM element of the first-fourth CiM elements 102a-102d is operated upon and is therefore retrieved from the respective CiM (e.g., “read (CiM, location, operation)”), stored into a CnM location of the first and second CnM elements 104a, 104b which then is made available to the CoM element 106 (e.g., “CnM, location, read”). The third instruction (e.g., line) is an operation (e.g., multiply, add, subtract, general matrix multiply, etc.) performed on variables a and b.

Pseudocode IV illustrates a way for the CoM element 106 to directly access a respective CiM of the first-fourth CiM elements 102a-102d:
1. x=read (respective CiM, location)
2. y=read (respective CiM, location, operation)
3. z=compute2 (a, b, c)

### Pseudo-Code IV: Arithmetic/CoM Instructions Directly Operating on a CiM Element of CiM Elements 102a-102d so that First and Second CnM Elements 104a, 104b are Bypassed

In pseudo-code IV, the first and the second instructions (first and second lines respectively), reflect that the CoM element 106 is directly accessing a location of a respective CiM of the CiM elements 102a-102d, with the third instruction (e.g., the third line) having an additional step of an operation (e.g., compute) being performed on the accessed data. In pseudo-code IV, CnM instructions are completely bypassed, and the CoM element 106 interacts with the respective CiM element as if the respective CiM element is a memory, or a memory instance that support very basic set of operations. Thus, the first-fourth CiM elements 102a-102d may operate as memories, in addition to executing compute. In some examples, the first-fourth CiM elements 102a-102d have outputs that directly connect to inputs of the first and second CnM elements 104a, 104b.

The first CnM element 104a is connected to a first multiplexer 116 that may selectively provide an output (e.g., output signal) of the first CnM element 104a to the CoM element 106, the first CiM element 102a and the second CiM element 102b. Thus, the first multiplexer 116 provides an output signal of the first CnM element 104a to one of the first and second CiM elements 102a, 102b. A first multi-connection switch 108 is provided to route the output of the first CnM element 104a to the first CiM element 102a and/or the second CiM element 102b.

The second CnM element 104b is connected to a second multiplexer 118 that may selectively provide an output of the second CnM element 104b to the CoM element 106, the third CiM element 102c and the fourth CiM element 102d. A second multi-connection switch 110 is provided to route the output of the second CnM element 104b to the third CiM element 102c or the fourth CiM element 102d.

A third multi-connection switch 112 is provided and selectively provides an input, that may originate from outside the compute and memory architecture 100, to the first and second multi-connection switches 108, 110. The third multi-connection switch 112 may also receive an output of the CoM element 106 via the multiplexer 116. The third multi-connection switch 112 may also route the output received from the CoM element 106 to the first and second multi-connection switches 108, 110.

The CoM element 106 is connected with a third multiplexer 114. The third multiplexer 114 may selectively route an output signal of the CoM element 106 to the third multi-connection switch 112 and an output. The third multi-connection switch 112 may provide the output signal of the CoM element 106 to the first multi-connection switch 108 or the second multi-connection switch 110, and the output signal may then be provided to one or more of the first-fourth CiMs elements 102a-102d. Thus, the third multiplexer 114 provides the output signal of the CoM element 106 to one or more of the first-fourth CiM element 102a-102d.

The compute and memory architecture 100 (e.g., a three-level hierarchical architecture) as illustrated herein forms an inherent three-level nested loop to execute numerous different AI algorithms or applications. Further, the hardware parallelism may also instantiate the first-fourth CiM elements 102a-102d, first and second CnM elements 104a, 104b and CoM element 106 in a tiled manner. While the number of illustrated levels is three, the compute and memory architecture 100 may be designed to have any arbitrary number of levels.

The CiM layer 102 (e.g., in-memory compute cores) may closely relate the processing and storage capabilities of a computer system into a single, memory-centric computing structure. In the CiM layer 102, computations may be performed directly in memory rather than moving data between the memory and a computation unit or processor. The first-fourth CIM elements 102a-102d may accelerate machine learning workloads such as AI and/or deep neural network (DNN) workloads. The mapping of workloads onto hardware plays a role in defining the performance and energy consumption in such applications. CIM elements 102a-102d may also be referred to as IMCCs. Notably, in the compute and memory architecture 100, the CiM layer 102 may perform first computations, the CnM layer 104 may perform a second computations and the CoM element 106 may perform third computations. The first, second and third computations may be distinct from one another, although there may be some overlap between computations executed with the CiM layer 102, the CnM layer 104 and the CoM element 106. Thus, the near proximity and hierarchical arrangement of the CiM layer 102, the CnM layer 104 and the CoM element 106 reduces overhead, latency and bandwidth since the first, second and third computations (which may be for AI and/or DNN workloads) may be executed in close proximity to each other.

It is worthwhile to note that the various components may be implemented in hardware circuitry and/or configurations. For example, the CiM layer 102, the CnM layer 104 and the CoM element 106 may be implemented in hardware implementations that may include configurable logic, fixed-functionality logic, or any combination thereof. Examples of configurable logic include suitably configured programmable logic arrays (PLAs), field programmable gate arrays (FPGAs), complex programmable logic devices (CPLDs), and general purpose microprocessors. Examples of fixed-functionality logic include suitably configured application specific integrated circuits (ASICs), general purpose microprocessor or combinational logic circuits, and sequential logic circuits or any combination thereof. The configurable or fixed-functionality logic can be implemented with complementary metal oxide semiconductor (CMOS) logic circuits, transistor-transistor logic (TTL) logic circuits, or other circuits.

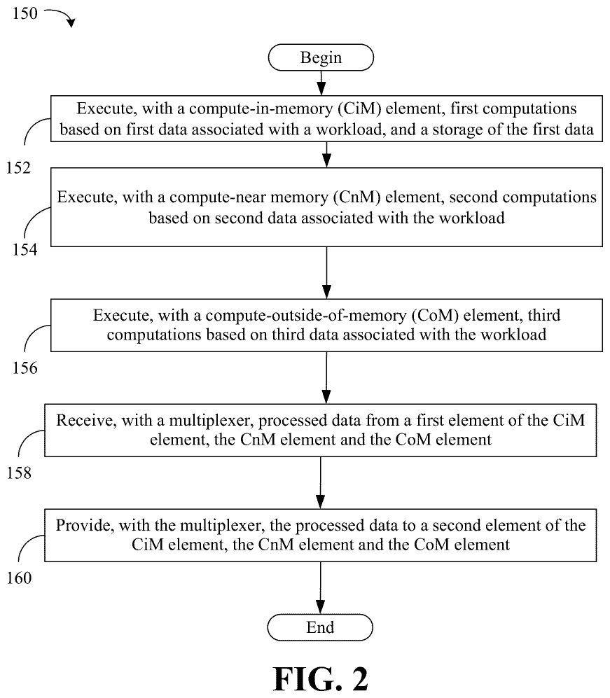

FIG. 2 shows a method 150 of executing a hierarchical compute and storage process according to embodiments herein. The method 150 may generally be implemented with the embodiments described herein, for example, the compute and memory architecture 100 (FIG. 1) already discussed. More particularly, the method 150 may be implemented in one or more modules as a set of logic instructions stored in a machine- or computer-readable storage medium such as random access memory (RAM), read only memory (ROM), programmable ROM (PROM), firmware, flash memory, etc., in hardware, or any combination thereof. For example, hardware implementations may include configurable logic, fixed-functionality logic, or any combination thereof. Examples of configurable logic include suitably configured PLAs, FPGAs, CPLDs, and general purpose microprocessors. Examples of fixed-functionality logic include suitably configured ASICs, general purpose microprocessor or combinational logic circuits, and sequential logic circuits or any combination thereof. The configurable or fixed-functionality logic can be implemented with CMOS logic circuits, TTL logic circuits, or other circuits.

For example, computer program code to carry out operations shown in the method 150 may be written in any combination of one or more programming languages, including an object-oriented programming language such as JAVA, SMALLTALK, C++ or the like and conventional procedural programming languages, such as the “C” programming language or similar programming languages. Additionally, logic instructions might include assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

Illustrated processing block 152 executes, with a compute-in-memory (CiM) element, first computations based on first data associated with a workload, and a storage of the first data. Illustrated processing block 154 executes, with a compute-near memory (CnM) element, second computations based on second data associated with the workload. Illustrated processing block 156 executes, with a compute-outside-of-memory (CoM) element, third computations based on third data associated with the workload. Illustrated processing block 158 receives, with a multiplexer, processed data from a first element of the CiM element, the CnM element and the CoM element. Illustrated processing block 160 provides, with the multiplexer, the processed data to a second element of the CiM element, the CnM element and the CoM element. The first computations, the second computations and the third computations are different from each other.

In some examples, the CiM element includes first and second CiM elements that have outputs directly connected to inputs of the CnM element. In some examples, the multiplexer includes first and second multiplexers, and the method 150 further comprises providing, with the first multiplexer, an output signal of the CnM element to the CiM element, and providing, with the second multiplexer, an output signal of the CoM element to the CiM element. In some examples, the method 150 includes storing, with the CiM element, the second data, and fetching, with the CnM element, the second data from the CiM element, the workload is associated with one or more of an artificial intelligence model or a machine learning model.

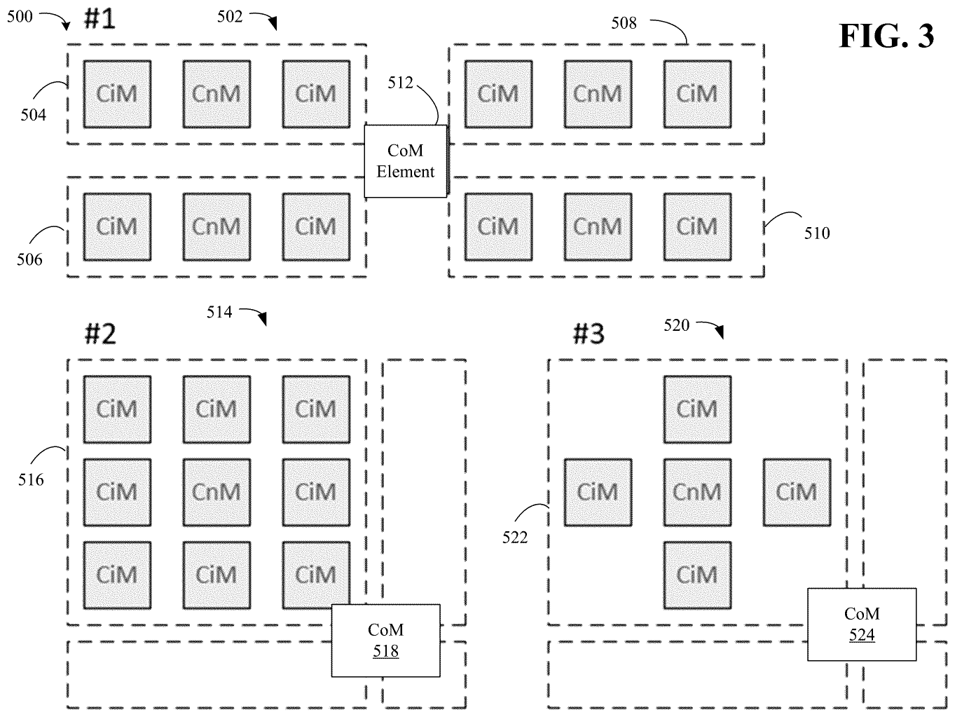

Turning now to FIG. 3, different arrangements 500 of CiM elements, CnM elements and CoM elements are illustrated. The different arrangements 500 may generally be implemented with the embodiments described herein, for example, the compute and memory architecture 100 (FIG. 1) and/or method 150 (FIG. 2) already discussed. For example, a first hierarchy 502 is illustrated. In the first hierarchy 502, different sets 504, 506, 508, 510 are illustrated. In each set of the different sets 504, 506, 508, 510, two CiMs elements are connected with a CnM element. The CnM elements of the different sets 504, 506, 508, 510 are connected with a CoM element 512, which in turn may be connected to the CiMs of the different sets 504, 506, 508, 510, similarly to as shown with respect to compute and memory architecture 100 (FIG. 1).

A second hierarchy 514 is illustrated. In the second hierarchy 514, one large CiM set 516 includes CiMs. The CiMs of the CiM set 516 are connected with a CoM 518, similarly to as shown with respect to compute and memory architecture 100 (FIG. 1). In the second hierarchy, a CnM is not provided.

A third hierarchy 520 is illustrated. In the third hierarchy 520, a set 522 includes four CiMs and one CnM that is connected with the four CiMs similarly to as shown with respect to compute and memory architecture 100 (FIG. 1). The CiMs and CnM of the set 522 are connected with a CoM 524, similarly to as shown with respect to compute and memory architecture 100 (FIG. 1).

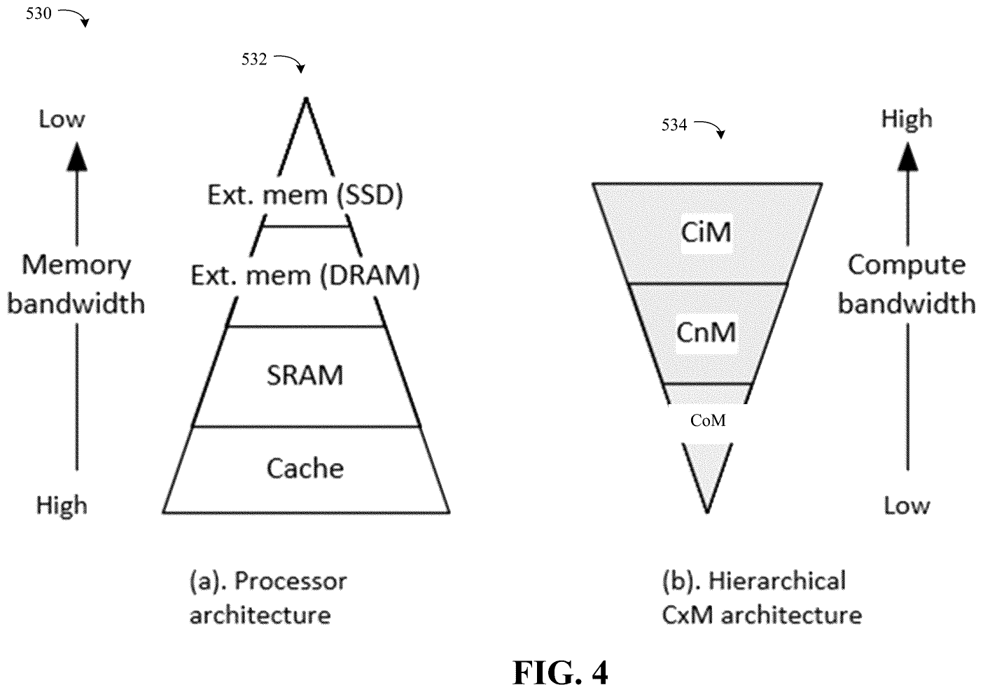

Turning now to FIG. 4, diagrams 530 of memory and compute bandwidth are illustrated. The diagrams 530 may generally be implemented with the embodiments described herein, for example, the compute and memory architecture 100 (FIG. 1), method 150 (FIG. 2) and/or different arrangements 500 (FIG. 3) already discussed. A CPU memory hierarchy 532 in a CPU (processor architecture) is illustrated. Examples herein extend the concept of memory hierarchy in CPUs and are applicable to inference accelerators. The hierarchy in the case of domain specific accelerators follows that of compute and memory architecture 100 (FIG. 1), while the enhanced compute hierarchy 534 shows the application of examples to different processor architectures. Unused CiM tiles may be repurposed for pure storage in both accelerators and CPUs. A micro-code may also be stored at the CnM level which the CnM tile itself will decode and issue commands and/or instructions selectively to CiMs and/or CnMs.

A majority of computations may occur at the top of the enhanced compute hierarchy 534. The top of the enhanced compute hierarchy 534 corresponds to the CiM core, which may be the equivalent of a CPU accessing the cache in existing CPU architectures as shown at CPU memory hierarchy 532.

There may be a minimal addition to the instruction set (e.g., for a CPU based implementation) to support examples of the hierarchy. Examples may not have to support a highly vectorized CPU core which will not only increase the CoM core but also increases the memory bandwidth to feed the vector-core.

The below list defines different supports for computation with the CoM, CiM and CnM:
1) CiM tile (e.g., SRAM macro based analog compute):
   a) Basic arithmetic (MULT/ADD/MAC),
   b) At least one set of operands are already stored as a part of the CiM macro, resulting in lower data movement.
   c) High power efficiency, due to low data movement and low power consumption of the computation core itself.
2) CnM tile (e.g., L2 cache, digital logic attached to memory).
   a) Intermediate arithmetic (simple activation, pooling layers etc.).
   b) Capacity to store small programs (microcode) that it can execute by itself. (Accumulation of a result, forward the data to a higher layer)
   c) Determine arithmetic operation type and forward to higher layer with a small Network-on-Chip (NOC) type routing capability.
3) CoM (e.g., CPU, arithmetic logic unit core, digital arithmetic core):
   a) Advanced arithmetic (sophisticated implementation for activations and other complex arithmetic operations).

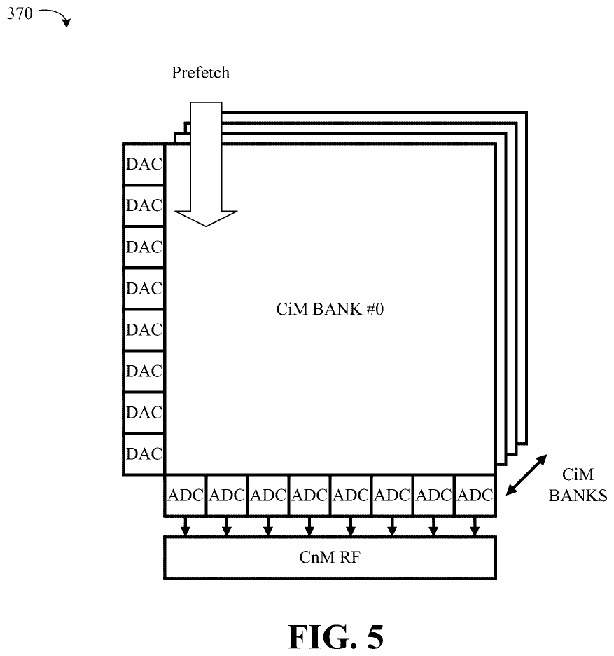

FIG. 5 illustrates a CiM prefetch process 370. The CiM prefetch process 370 may generally be implemented with the examples described herein, for example, the compute and memory architecture 100 (FIG. 1), method 150 (FIG. 2), different arrangements 500 (FIG. 3) and/or diagrams 530 (FIG. 4) already discussed. The CiM prefetch process 370 prefetches data to be stored into the CiM bank as indicated by the prefetch arrow. That is physical values are loaded into the CiM bank (e.g., an SRAM array). A digital-to-analog converter (DAC) and analog-to-digital converter (ADC) are provided. The DAC may convert digital signals (e.g., output signal from a CoM or CnM) to analog signals, and then convert output data from the CiM from analog signal to digital signals.

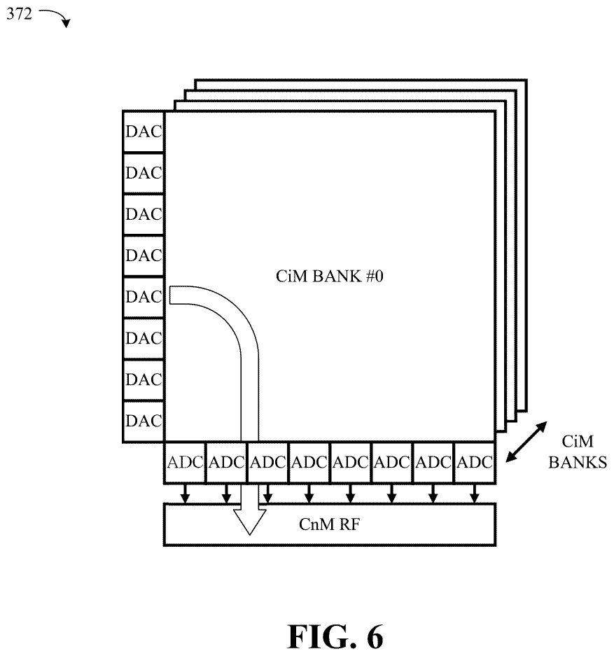

FIG. 6 illustrates a CiM operation process 372 (e.g., 64×64 by 64×1 8-bit Matrix-Vector Multiply). The CiM operation process 372 may generally be implemented with the embodiments described herein, for example, the compute and memory architecture 100 (FIG. 1), method 150 (FIG. 2), different arrangements 500 (FIG. 3), diagrams 530 (FIG. 4) and/or CiM prefetch process 370 (FIG. 5). The CiM operation process 372 executes a CiM matrix vector multiplication where inputs from the DACs are being processed in the CiM bank, output through ADCs and then stored into a register (e.g., CnM RF).

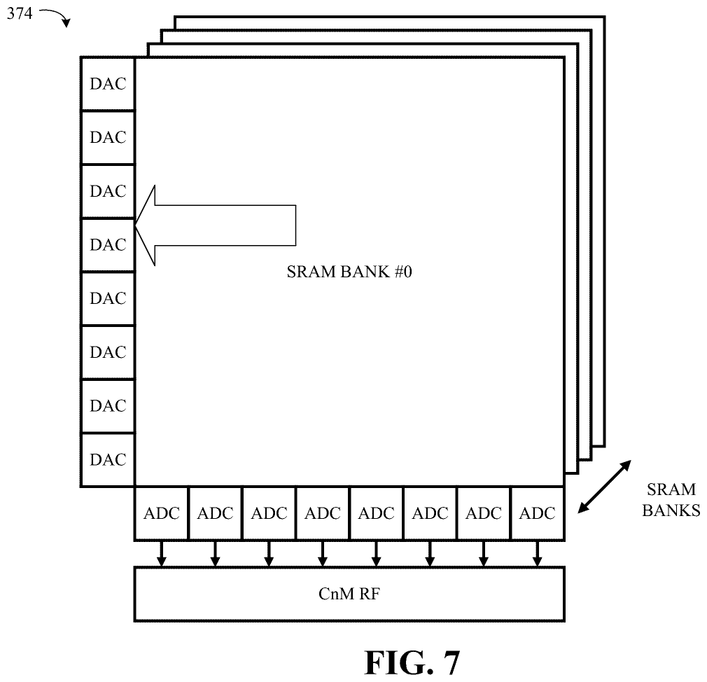

FIG. 7 illustrates a CiM DAC load process 374 to retrieve data from memory. The CiM DAC load process 374 may generally be implemented with the embodiments described herein, for example, the compute and memory architecture 100 (FIG. 1), method 150 (FIG. 2), different arrangements 500 (FIG. 3), diagrams 530 (FIG. 4), CiM prefetch process 370 (FIG. 5) and/or CiM operation process 372 (FIG. 6). already discussed. The CiM architecture executes a CiM data load. For example, the CiM architecture may load CiM data buffer from a memory address into DACs. In some examples, the CiM DAC load process 374 (load CiM DAC Buffer from SRAM address) fully loads data for fully connected (FC) layers and executes a partial load for Convolutional (CONV) layers.

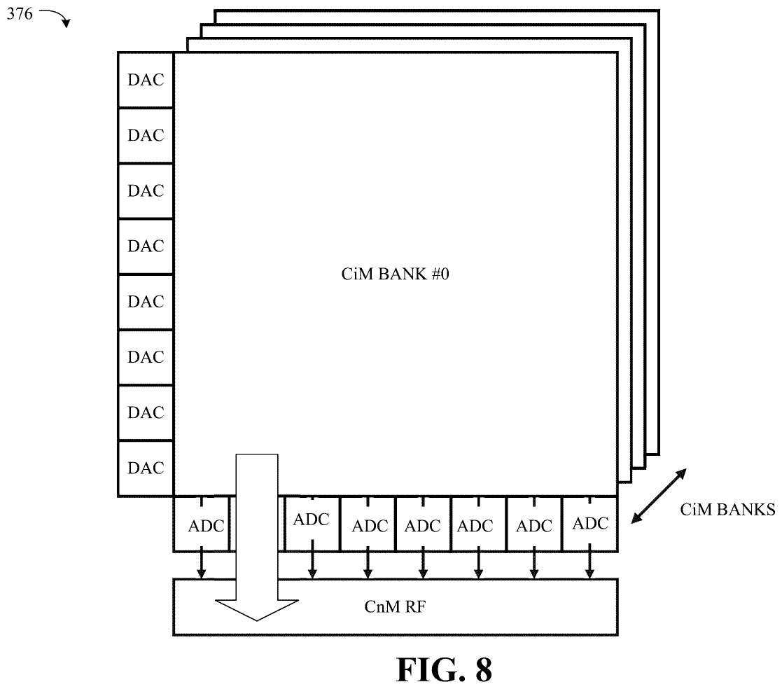

FIG. 8 illustrates a CiM partial load process 376. The CiM partial load process 376 may generally be implemented with the embodiments described herein, for example, the compute and memory architecture 100 (FIG. 1), method 150 (FIG. 2), different arrangements 500 (FIG. 3), diagrams 530 (FIG. 4), CiM prefetch process 370 (FIG. 5), CiM operation process 372 (FIG. 6) and/or CiM DAC load process 374 (FIG. 7) already discussed. The CiM partial load process 376 executes a CnM data load of a partial result, converts the partial result into the digital domain from the analog domain and stores the digital partial result into a memory register file.

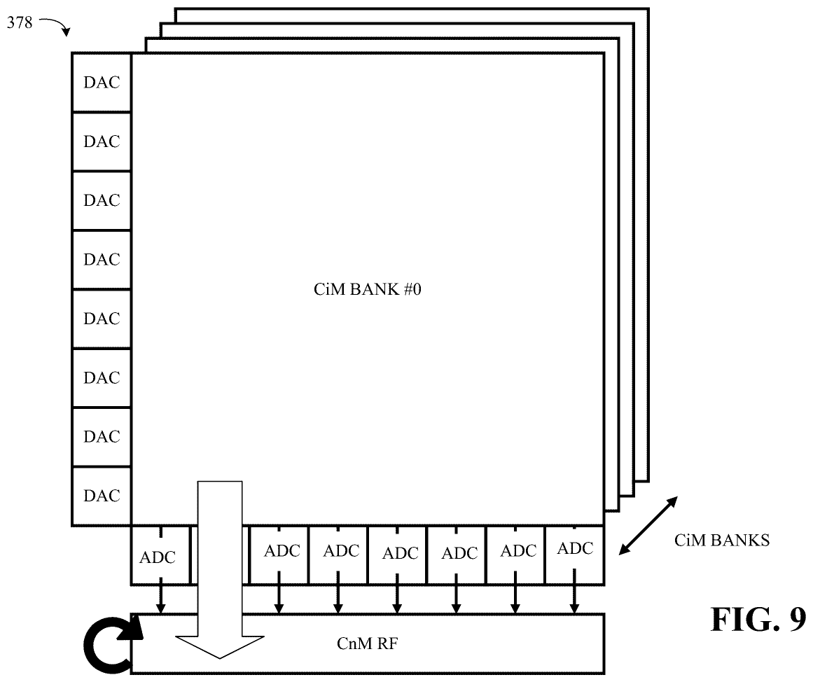

FIG. 9 illustrates a CiM addition and accumulation process 378. The CiM addition and accumulation process 378 may generally be implemented with the embodiments described herein, for example, the compute and memory architecture 100 (FIG. 1), method 150 (FIG. 2), different arrangements 500 (FIG. 3), diagrams 530 (FIG. 4), CiM prefetch process 370 (FIG. 5), CiM operation process 372 (FIG. 6), CiM DAC load process 374 (FIG. 7) and/or CiM partial load process 376 (FIG. 8) already discussed. In this example, the CiM addition and accumulation process 378 retrieves data from the CiM bank #0, accumulates a partial product and adds the partial to another partial product stored in a memory register file (CnM RF). The instruction CnM Add (Accum. SRAM ADDR to CnM RF) may be provided to execute the above.

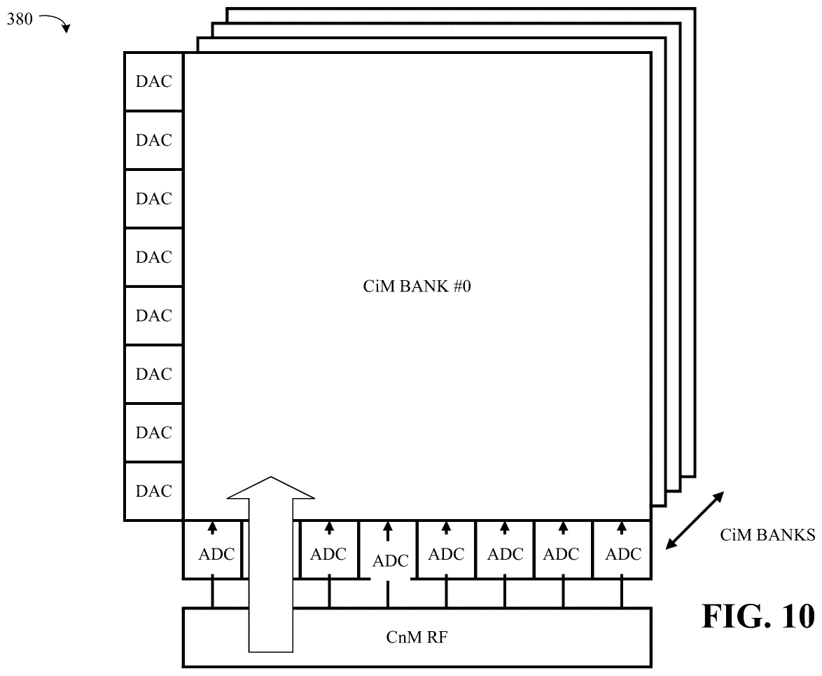

FIG. 10 illustrates a CiM memory storage process 380. The CiM memory storage process 380 may generally be implemented with the embodiments described herein, for example, the compute and memory architecture 100 (FIG. 1), method 150 (FIG. 2), different arrangements 500 (FIG. 3), diagrams 530 (FIG. 4), CiM prefetch process 370 (FIG. 5), CiM operation process 372 (FIG. 6), CiM DAC load process 374 (FIG. 7), CiM partial load process 376 (FIG. 8) and/or CiM addition and accumulation process 378 (FIG. 9) already discussed. The CiM architecture moves data from the accumulator (CnM RF) into the memory banks of the CiM bank. Data is loaded from the memory register file to the CiM bank #0. The CiM memory storage process 380 may implement a CnM Store (Store CnM RF to SRAM ADDR).

The aforementioned CiM prefetch process 370 (FIG. 5), CiM operation process 372 (FIG. 6), CiM DAC load process 374 (FIG. 7), CiM partial load process 376 (FIG. 8), CiM addition and accumulation process 378 (FIG. 9) and/or CiM memory storage process 380 (FIG. 10) may be combined to execute various operations together. For example, multiplication, accumulation, matrix, vector-vector and matrix-matrix operations at different precisions may be supported. For example, weights may be loaded into a CiM bank with a prefetch, inputs may be loaded into the DAC, CiM may be executed and the corresponding PPs stored into a register file, switch CiM banks to execute another operation and store partial results into the register file, re-load the PPs into the CiM to execute other operations, and so forth.

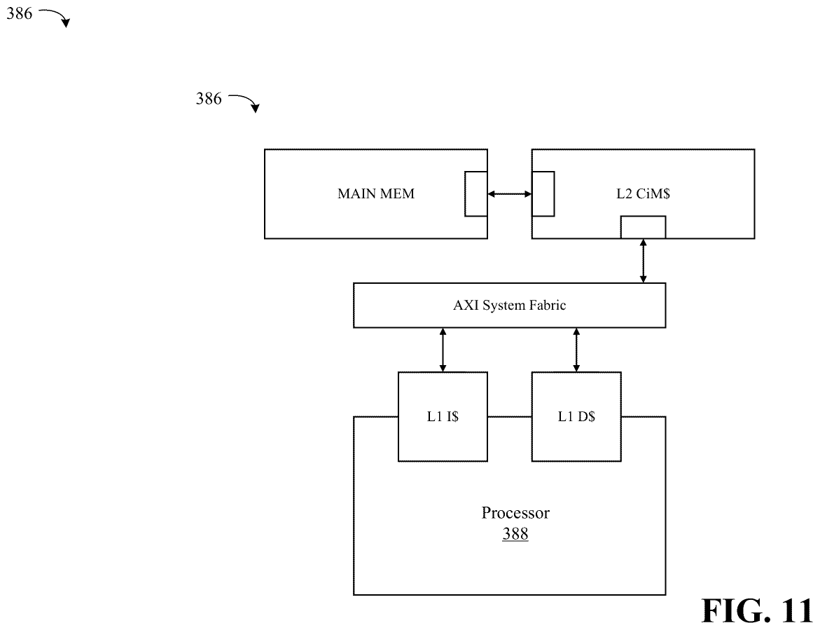

FIG. 11 illustrates a memory storage architecture 386. The memory storage architecture 386 may generally be implemented with the embodiments described herein, for example, the compute and memory architecture 100 (FIG. 1), method 150 (FIG. 2), different arrangements 500 (FIG. 3), diagrams 530 (FIG. 4), CiM prefetch process 370 (FIG. 5), CiM operation process 372 (FIG. 6), CiM DAC load process 374 (FIG. 7), CiM partial load process 376 (FIG. 8), CiM addition and accumulation process 378 (FIG. 9) and/or the CiM memory storage process 380 (FIG. 10) already discussed. In the memory storage architecture 386, data is moved from a main memory to a processor 388.

The memory storage architecture 386 shows the example system with the processor 388 (e.g., including 16 KB L1 data and instruction caches, with a 128 KB, CiM and CnM enabled, shared L2 Cache, and a bandwidth limited connection to main memory (32 Gb/s)). The speedups for the examples herein, such as the processor 388, relative to CPU baseline (e.g., RISC-V) to execute operations for various number formats (e.g., INT8, INT16, INT32, FP32, etc.) is significant.

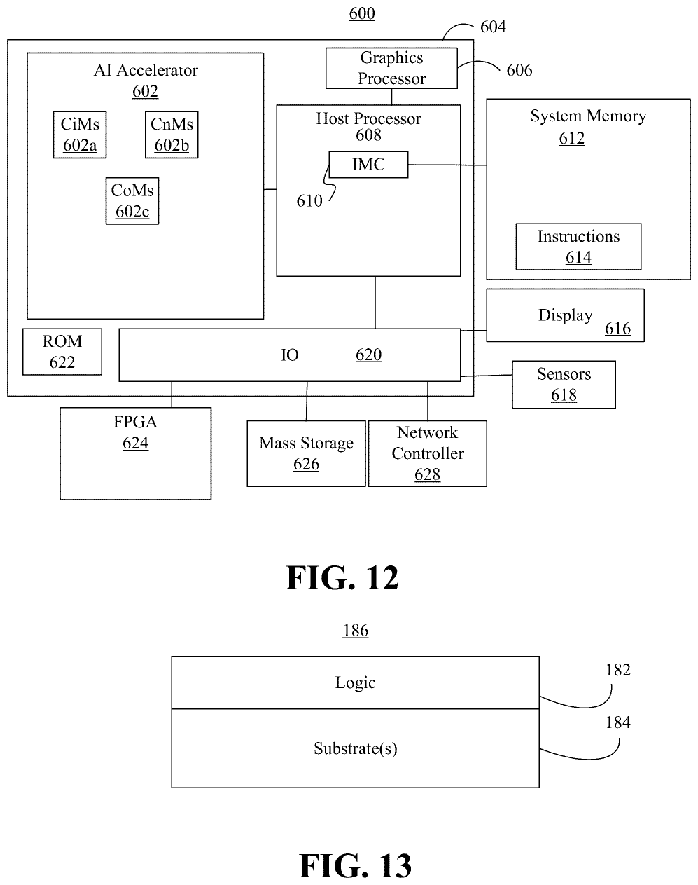

Turning now to FIG. 12, a computation enhanced computing system 600 is shown. The computation enhanced computing system 600 may generally be part of an electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot, manufacturing robot, autonomous vehicle, industrial robot, etc.), edge device (e.g., mobile phone, desktop, etc.) etc., or any combination thereof. In the illustrated example, the computing system 600 includes a host processor 608 (e.g., CPU) having an integrated memory controller (IMC) 610 that is coupled to a system memory 612.

The illustrated computing system 600 also includes an input output (IO) module 620 implemented together with the host processor 608, the graphics processor 606 (e.g., GPU), ROM 622, and AI accelerator 602 on a semiconductor die 604 as a system on chip (SoC). The illustrated IO module 620 communicates with, for example, a display 616 (e.g., touch screen, liquid crystal display/LCD, light emitting diode/LED display), a network controller 628 (e.g., wired and/or wireless), FPGA 624 and mass storage 626 (e.g., hard disk drive/HDD, optical disk, solid state drive/SSD, flash memory). The IO module 620 also communicates with sensors 618 (e.g., video sensors, audio sensors, proximity sensors, heat sensors, etc.).

The SoC 604 may further include processors (not shown) and/or the AI accelerator 602 dedicated to artificial intelligence (AI) and/or neural network (NN) processing. For example, the SoC 604 may include vision processing units (VPUs,) and/or other AI/NN-specific processors such as the AI accelerator 602, etc. In some embodiments, any aspect of the embodiments described herein may be implemented in the processors, such as the graphics processor 606 and/or the host processor 608, and in the accelerators dedicated to AI and/or NN processing such as AI accelerator 602 or other devices such as the FPGA 624. In this particular example, the AI accelerator 602 may include CiMs 602a, CnMs 602b and CoMs 602c that are connected in a hierarchical fashion as described herein to increase throughput, decrease latency and reduce bandwidth.

The graphics processor 606, AI accelerator 602 and/or the host processor 608 may execute instructions 614 retrieved from the system memory 612 (e.g., a dynamic random-access memory) and/or the mass storage 626 to implement aspects as described herein. In some examples, when the instructions 614 are executed, the computing system 600 may implement one or more aspects of the embodiments described herein. For example, the computing system 600 may implement one or more aspects of the examples described herein, for example, the compute and memory architecture 100 (FIG. 1), method 150 (FIG. 2), different arrangements 500 (FIG. 3), diagrams 530 (FIG. 4), CiM prefetch process 370 (FIG. 5), CiM operation process 372 (FIG. 6), CiM DAC load process 374 (FIG. 7), CiM partial load process 376 (FIG. 8), CiM addition and accumulation process 378 (FIG. 9), the CiM memory storage process 380 (FIG. 10) and/or memory storage architecture 386 (FIG. 11) already discussed. The illustrated computing system 600 is therefore considered to be memory and performance-enhanced at least to the extent that the computing system 600 may execute machine learning operations.

FIG. 13 shows a semiconductor apparatus 186 (e.g., chip, die, package). The illustrated apparatus 186 includes one or more substrates 184 (e.g., silicon, sapphire, gallium arsenide) and logic 182 (e.g., transistor array and other integrated circuit/IC components) coupled to the substrate(s) 184. In an embodiment, the apparatus 186 is operated in an application development stage and the logic 182 performs one or more aspects of the embodiments described herein. For example, the compute and memory architecture 100 (FIG. 1), method 150 (FIG. 2), different arrangements 500 (FIG. 3), diagrams 530 (FIG. 4), CiM prefetch process 370 (FIG. 5), CiM operation process 372 (FIG. 6), CiM DAC load process 374 (FIG. 7), CiM partial load process 376 (FIG. 8), CiM addition and accumulation process 378 (FIG. 9), the CiM memory storage process 380 (FIG. 10) and/or memory storage architecture 386 (FIG. 11) already discussed. The logic 182 may be implemented at least partly in configurable logic or fixed-functionality hardware logic. In one example, the logic 182 includes transistor channel regions that are positioned (e.g., embedded) within the substrate(s) 184. Thus, the interface between the logic 182 and the substrate(s) 184 may not be an abrupt junction. The logic 182 may also be considered to include an epitaxial layer that is grown on an initial wafer of the substrate(s) 184.

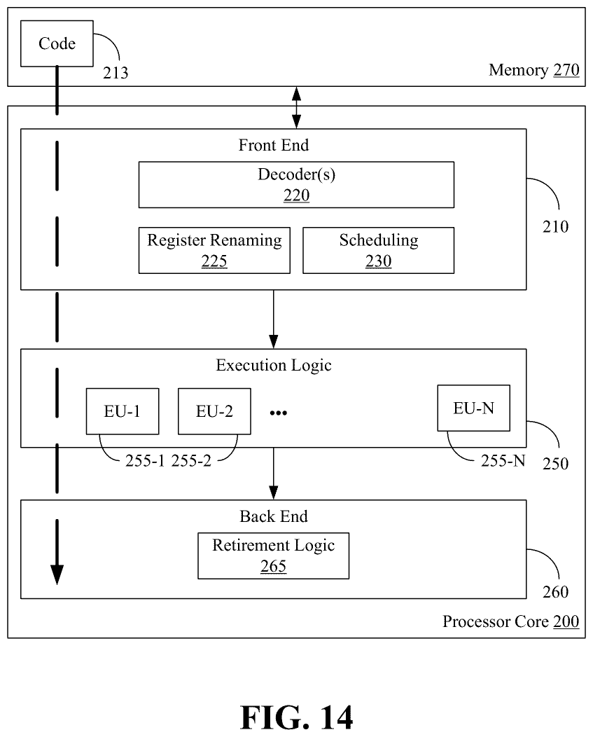

FIG. 14 illustrates a processor core 200 according to one embodiment. The processor core 200 may be the core for any type of processor, such as a micro-processor, an embedded processor, a digital signal processor (DSP), a network processor, or other device to execute code. Although only one processor core 200 is illustrated in FIG. 14, a processing element may alternatively include more than one of the processor core 200 illustrated in FIG. 14. The processor core 200 may be a single-threaded core or, for at least one embodiment, the processor core 200 may be multithreaded in that it may include more than one hardware thread context (or “logical processor”) per core.

FIG. 14 also illustrates a memory 270 coupled to the processor core 200. The memory 270 may be any of a wide variety of memories (including various layers of memory hierarchy) as are known or otherwise available to those of skill in the art. The memory 270 may include one or more code 213 instruction(s) to be executed by the processor core 200, wherein the code 213 may implement one or more aspects of the embodiments such as, for example, the compute and memory architecture 100 (FIG. 1), method 150 (FIG. 2), different arrangements 500 (FIG. 3), diagrams 530 (FIG. 4), CiM prefetch process 370 (FIG. 5), CiM operation process 372 (FIG. 6), CiM DAC load process 374 (FIG. 7), CiM partial load process 376 (FIG. 8), CiM addition and accumulation process 378 (FIG. 9), the CiM memory storage process 380 (FIG. 10) and/or memory storage architecture 386 (FIG. 11) already discussed. The processor core 200 follows a program sequence of instructions indicated by the code 213. Each instruction may enter a front end portion 210 and be processed by one or more decoders 220. The decoder 220 may generate as its output a micro operation such as a fixed width micro operation in a predefined format, or may generate other instructions, microinstructions, or control signals which reflect the original code instruction. The illustrated front end portion 210 also includes register renaming logic 225 and scheduling logic 230, which generally allocate resources and queue the operation corresponding to the convert instruction for execution.

The processor core 200 is shown including execution logic 250 having a set of execution units 255-1 through 255-N. Some embodiments may include several execution units dedicated to specific functions or sets of functions. Other embodiments may include only one execution unit or one execution unit that can perform a particular function. The illustrated execution logic 250 performs the operations specified by code instructions.

After completion of execution of the operations specified by the code instructions, back end logic 260 retires the instructions of the code 213. In one embodiment, the processor core 200 allows out of order execution but requires in order retirement of instructions. Retirement logic 265 may take a variety of forms as known to those of skill in the art (e.g., re-order buffers or the like). In this manner, the processor core 200 is transformed during execution of the code 213, at least in terms of the output generated by the decoder, the hardware registers and tables utilized by the register renaming logic 225, and any registers (not shown) modified by the execution logic 250.

Although not illustrated in FIG. 14, a processing element may include other elements on chip with the processor core 200. For example, a processing element may include memory control logic along with the processor core 200. The processing element may include I/O control logic and/or may include I/O control logic integrated with memory control logic. The processing element may also include one or more caches.

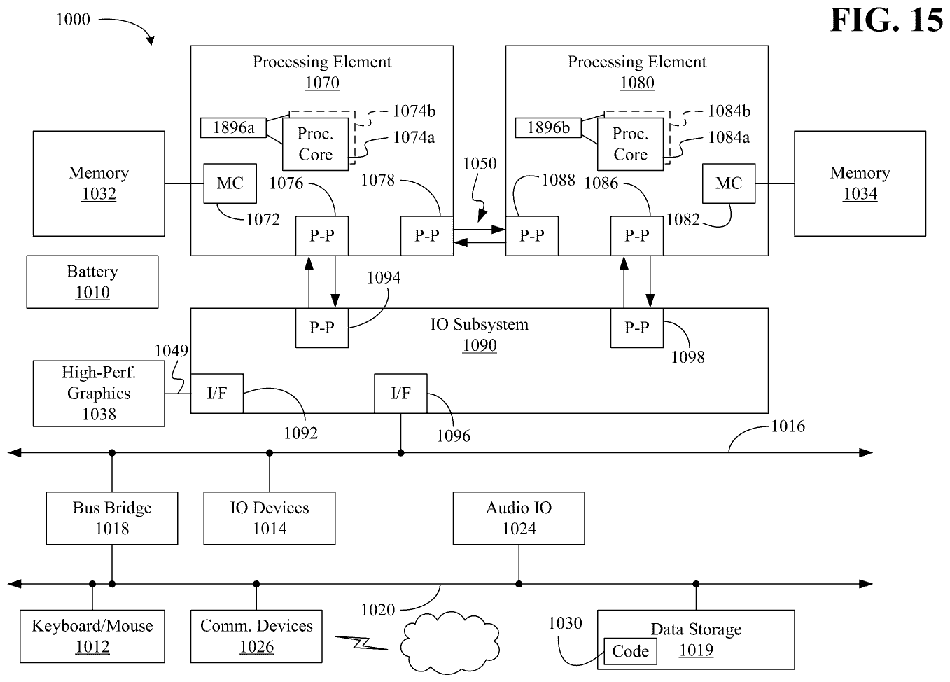

Referring now to FIG. 15, shown is a block diagram of a computing system 1000 embodiment in accordance with an embodiment. Shown in FIG. 15 is a multiprocessor system 1000 that includes a first processing element 1070 and a second processing element 1080. While two processing elements 1070 and 1080 are shown, it is to be understood that an embodiment of the system 1000 may also include only one such processing element.

The system 1000 is illustrated as a point-to-point interconnect system, wherein the first processing element 1070 and the second processing element 1080 are coupled via a point-to-point interconnect 1050. It should be understood any or all the interconnects illustrated in FIG. 15 may be implemented as a multi-drop bus rather than point-to-point interconnect.

As shown in FIG. 15, each of processing elements 1070 and 1080 may be multicore processors, including first and second processor cores (i.e., processor cores 1074a and 1074b and processor cores 1084a and 1084b). Such cores 1074a, 1074b, 1084a, 1084b may be configured to execute instruction code in a manner like that discussed above in connection with FIG. 14.

Each processing element 1070, 1080 may include at least one shared cache 1896a, 1896b. The shared cache 1896a, 1896b may store data (e.g., instructions) that are utilized by one or more components of the processor, such as the cores 1074a, 1074b and 1084a, 1084b, respectively. For example, the shared cache 1896a, 1896b may locally cache data stored in a memory 1032, 1034 for faster access by components of the processor. In one or more embodiments, the shared cache 1896a, 1896b may include one or more mid-level caches, such as level 2 (L2), level 3 (L3), level 4 (L4), or other levels of cache, a last level cache (LLC), and/or combinations thereof.

While shown with only two processing elements 1070, 1080, it is to be understood that the scope of the embodiments is not so limited. In other embodiments, one or more additional processing elements may be present in a given processor. Alternatively, one or more of processing elements 1070, 1080 may be an element other than a processor, such as an accelerator or a field programmable gate array. For example, additional processing element(s) may include additional processors(s) that are the same as a first processor 1070, additional processor(s) that are heterogeneous or asymmetric to processor a first processor 1070, accelerators (such as, e.g., graphics accelerators or digital signal processing (DSP) units), field programmable gate arrays, or any other processing element. There can be a variety of differences between the processing elements 1070, 1080 in terms of a spectrum of metrics of merit including architectural, micro architectural, thermal, power consumption characteristics, and the like. These differences may effectively manifest themselves as asymmetry and heterogeneity amongst the processing elements 1070, 1080. For at least one embodiment, the various processing elements 1070, 1080 may reside in the same die package.

The first processing element 1070 may further include memory controller logic (MC) 1072 and point-to-point (P-P) interfaces 1076 and 1078. Similarly, the second processing element 1080 may include a MC 1082 and P-P interfaces 1086 and 1088. As shown in FIG. 15, MC's 1072 and 1082 couple the processors to respective memories, namely a memory 1032 and a memory 1034, which may be portions of main memory locally attached to the respective processors. While the MC 1072 and 1082 is illustrated as integrated into the processing elements 1070, 1080, for alternative embodiments the MC logic may be discrete logic outside the processing elements 1070, 1080 rather than integrated therein.

The first processing element 1070 and the second processing element 1080 may be coupled to an I/O subsystem 1090 via P-P interconnects 1076 1086, respectively. As shown in FIG. 15, the I/O subsystem 1090 includes P-P interfaces 1094 and 1098. Furthermore, I/O subsystem 1090 includes an interface 1092 to couple I/O subsystem 1090 with a high performance graphics engine 1038. In one embodiment, bus 1049 may be used to couple the graphics engine 1038 to the I/O subsystem 1090. Alternately, a point-to-point interconnect may couple these components.

In turn, I/O subsystem 1090 may be coupled to a first bus 1016 via an interface 1096. In one embodiment, the first bus 1016 may be a Peripheral Component Interconnect (PCI) bus, or a bus such as a PCI Express bus or another third generation I/O interconnect bus, although the scope of the embodiments is not so limited.

As shown in FIG. 15, various I/O devices 1014 (e.g., biometric scanners, speakers, cameras, sensors) may be coupled to the first bus 1016, along with a bus bridge 1018 which may couple the first bus 1016 to a second bus 1020. In one embodiment, the second bus 1020 may be a low pin count (LPC) bus. Various devices may be coupled to the second bus 1020 including, for example, a keyboard/mouse 1012, communication device(s) 1026, and a data storage unit 1019 such as a disk drive or other mass storage device which may include code 1030, in one embodiment. The illustrated code 1030 may implement the one or more aspects of such as, for example, the compute and memory architecture 100 (FIG. 1), method 150 (FIG. 2), different arrangements 500 (FIG. 3), diagrams 530 (FIG. 4), CiM prefetch process 370 (FIG. 5), CiM operation process 372 (FIG. 6), CiM DAC load process 374 (FIG. 7), CiM partial load process 376 (FIG. 8), CiM addition and accumulation process 378 (FIG. 9), the CiM memory storage process 380 (FIG. 10) and/or memory storage architecture 386 (FIG. 11) already discussed. Further, an audio I/O 1024 may be coupled to second bus 1020 and a battery 1010 may supply power to the computing system 1000.

Note that other embodiments are contemplated. For example, instead of the point-to-point architecture of FIG. 15, a system may implement a multi-drop bus or another such communication topology. Also, the elements of FIG. 15 may alternatively be partitioned using more or fewer integrated chips than shown in FIG. 15.

### ADDITIONAL NOTES AND EXAMPLES

Example 1 includes a computing system comprising a compute-in-memory (CiM) element to execute first computations based on first data associated with a workload, and store the first data, a compute-near memory (CnM) element to execute second computations based on second data associated with the workload, a compute-outside-of-memory (CoM) element that executes third computations based on third data associated with the workload, and a multiplexer to receive processed data from a first element of the CiM element, the CnM element and the CoM element, and provide the processed data to a second element of the CiM element, the CnM element and the CoM element.

Example 2 includes the computing system of Example 1, where the first computations, the second computations and the third computations are different from each other.

Example 3 includes the computing system of Example 1, where the CiM element includes first and second CiM elements that have outputs directly connected to inputs of the CnM element.

Example 4 includes the computing system of Example 1, where the multiplexer provides an output signal of the CnM element to the CiM element.

Example 5 includes the computing system of Example 1, where the multiplexer provides an output signal of the CoM element to the CiM element.

Example 6 includes the computing system of Example 1, where the CiM element stores the second data, and the CnM element fetches the second data from the CiM element.

Example 7 includes the computing system of Example 1, where the CiM element, the CnM element and CoM element each include logic coupled to one or more substrates, where the logic is implemented at least partly in one or more of configurable logic or fixed-functionality hardware logic, and where the workload is associated with one or more of an artificial intelligence model or a machine learning model.

Example 8 includes semiconductor apparatus comprising one or more substrates, and logic coupled to the one or more substrates, where the logic is implemented at least partly in one or more of configurable logic or fixed-functionality hardware logic, the logic coupled to the one or more substrates to execute, with a compute-in-memory (CiM) element, first computations based on first data associated with a workload, and a storage of the first data, execute, with a compute-near memory (CnM) element, second computations based on second data associated with the workload, execute, with a compute-outside-of-memory (CoM) element, third computations based on third data associated with the workload, receive, with a multiplexer, processed data from a first element of the CiM element, the CnM element and the CoM element, and provide, with the multiplexer, the processed data to a second element of the CiM element, the CnM element and the CoM element.

Example 9 includes the apparatus of Example 8, where the first computations, the second computations and the third computations are different from each other.

Example 10 includes the apparatus of Example 8, where the CiM element includes first and second CiM elements that have outputs directly connected to inputs of the CnM element.

Example 11 includes the apparatus of Example 8, where the logic coupled to the one or more substrates is to provide, with the multiplexer, an output signal of the CnM element to the CiM element.

Example 12 includes the apparatus of Example 8, where the logic coupled to the one or more substrates is to provide, with the multiplexer, an output signal of the CoM element to the CiM element.

Example 13 includes the apparatus of Example 8, where the logic coupled to the one or more substrates is to store, with the CiM element, the second data, and fetch, with the CnM element, the second data from the CiM element.

Example 14 includes the apparatus of Example 8, where the workload is associated with one or more of an artificial intelligence model or a machine learning model.

Example 15 includes the apparatus of Example 8, where the logic coupled to the one or more substrates includes transistor channel regions that are positioned within the one or more substrates.

Example 16 includes method comprising executing, with a compute-in-memory (CiM) element, first computations based on first data associated with a workload, and a storage of the first data, executing, with a compute-near memory (CnM) element, second computations based on second data associated with the workload, executing, with a compute-outside-of-memory (CoM) element, third computations based on third data associated with the workload, receiving, with a multiplexer, processed data from a first element of the CiM element, the CnM element and the CoM element, and providing, with the multiplexer, the processed data to a second element of the CiM element, the CnM element and the CoM element.

Example 17 includes the method of Example 16, where the first computations, the second computations and the third computations are different from each other.

Example 18 includes the method of Example 16, where the CiM element includes first and second CiM elements that have outputs directly connected to inputs of the CnM element.

Example 19 includes the method of Example 16, where the multiplexer includes first and second multiplexers, and the method further comprises providing, with the first multiplexer, an output signal of the CnM element to the CiM element, and providing, with the second multiplexer, an output signal of the CoM element to the CiM element.

Example 20 includes the method of Example 16, further comprising storing, with the CiM element, the second data, and fetching, with the CnM element, the second data from the CiM element, where the CiM element, the CnM element and CoM element each include logic coupled to one or more substrates, where the logic is implemented at least partly in one or more of configurable logic or fixed-functionality hardware logic, and where the workload is associated with one or more of an artificial intelligence model or a machine learning model.

Example 21 includes an apparatus comprising means for executing, with a compute-in-memory (CiM) element, first computations based on first data associated with a workload, and a storage of the first data, means for executing, with a compute-near memory (CnM) element, second computations based on second data associated with the workload, means for executing, with a compute-outside-of-memory (CoM) element, third computations based on third data associated with the workload, means for receiving, with a multiplexer, processed data from a first element of the CiM element, the CnM element and the CoM element, and means for providing, with the multiplexer, the processed data to a second element of the CiM element, the CnM element and the CoM element.

Example 22 includes the apparatus of Example 21, where the first computations, the second computations and the third computations are different from each other.

Example 23 includes the apparatus of Example 21, where the CiM element includes first and second CiM elements that have outputs directly connected to inputs of the CnM element.

Example 24 includes the apparatus of Example 21, where the multiplexer includes first and second multiplexers, and the apparatus further comprises means for providing, with the first multiplexer, an output signal of the CnM element to the CiM element, and means for providing, with the second multiplexer, an output signal of the CoM element to the CiM element.

Example 23 includes the apparatus of Example 21, further comprising means for storing, with the CiM element, the second data, and means for fetching, with the CnM element, the second data from the CiM element, where the CiM element, the CnM element and CoM element each include logic coupled to one or more substrates, where the logic is implemented at least partly in one or more of configurable logic or fixed-functionality hardware logic, and where the workload is associated with one or more of an artificial intelligence model or a machine learning model.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical, or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A, B, C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a compute-in-memory (CiM) element to execute first computations based on first data associated with a workload, and store the first data;
a compute-near memory (CnM) element to execute second computations based on second data associated with the workload;
a compute-outside-of-memory (CoM) element that executes third computations based on third data associated with the workload; and
a multiplexer to receive processed data from a first element of the CiM element, the CnM element and the CoM element, and provide the processed data to a second element of the CiM element, the CnM element and the CoM element.

2. The computing system of claim 1, wherein the first computations, the second computations and the third computations are different from each other.

3. The computing system of claim 1, wherein the CiM element includes first and second CiM elements that have outputs directly connected to inputs of the CnM element.

4. The computing system of claim 1, wherein the multiplexer provides an output signal of the CnM element to the CiM element.

5. The computing system of claim 1, wherein the multiplexer provides an output signal of the CoM element to the CiM element.

6. The computing system of claim 1, wherein the CiM element stores the second data, and the CnM element fetches the second data from the CiM element.

7. The computing system of claim 1,
wherein the CiM element, the CnM element and CoM element each include logic coupled to one or more substrates, wherein the logic is implemented at least partly in one or more of configurable logic or fixed-functionality hardware logic, and
wherein the workload is associated with one or more of an artificial intelligence model or a machine learning model.

8. A semiconductor apparatus comprising:
one or more substrates; and
logic coupled to the one or more substrates, wherein the logic is implemented at least partly in one or more of configurable logic or fixed-functionality hardware logic, the logic coupled to the one or more substrates to:
execute, with a compute-in-memory (CiM) element, first computations based on first data associated with a workload, and a storage of the first data,
execute, with a compute-near memory (CnM) element, second computations based on second data associated with the workload,
execute, with a compute-outside-of-memory (CoM) element, third computations based on third data associated with the workload,
receive, with a multiplexer, processed data from a first element of the CiM element, the CnM element and the CoM element, and
provide, with the multiplexer, the processed data to a second element of the CiM element, the CnM element and the CoM element.

9. The apparatus of claim 8, wherein the first computations, the second computations and the third computations are different from each other.

10. The apparatus of claim 8, wherein the CiM element includes first and second CiM elements that have outputs directly connected to inputs of the CnM element.

11. The apparatus of claim 8, wherein the logic coupled to the one or more substrates is to:
provide, with the multiplexer, an output signal of the CnM element to the CiM element.

12. The apparatus of claim 8, wherein the logic coupled to the one or more substrates is to:
provide, with the multiplexer, an output signal of the CoM element to the CiM element.

13. The apparatus of claim 8, wherein the logic coupled to the one or more substrates is to:
store, with the CiM element, the second data; and
fetch, with the CnM element, the second data from the CiM element.

14. The apparatus of claim 8, wherein the workload is associated with one or more of an artificial intelligence model or a machine learning model.

15. The apparatus of claim 8, wherein the logic coupled to the one or more substrates includes transistor channel regions that are positioned within the one or more substrates.

16. A method comprising:
executing, with a compute-in-memory (CiM) element, first computations based on first data associated with a workload, and a storage of the first data;
executing, with a compute-near memory (CnM) element, second computations based on second data associated with the workload;
executing, with a compute-outside-of-memory (CoM) element, third computations based on third data associated with the workload;
receiving, with a multiplexer, processed data from a first element of the CiM element, the CnM element and the CoM element; and
providing, with the multiplexer, the processed data to a second element of the CiM element, the CnM element and the CoM element.

17. The method of claim 16, wherein the first computations, the second computations and the third computations are different from each other.

18. The method of claim 16, wherein the CiM element includes first and second CiM elements that have outputs directly connected to inputs of the CnM element.

19. The method of claim 16, wherein the multiplexer includes first and second multiplexers, and the method further comprises:
providing, with the first multiplexer, an output signal of the CnM element to the CiM element; and
providing, with the second multiplexer, an output signal of the CoM element to the CiM element.

20. The method of claim 16, further comprising:
storing, with the CiM element, the second data; and
fetching, with the CnM element, the second data from the CiM element,
wherein the CiM element, the CnM element and CoM element each include logic coupled to one or more substrates, wherein the logic is implemented at least partly in one or more of configurable logic or fixed-functionality hardware logic, and
wherein the workload is associated with one or more of an artificial intelligence model or a machine learning model.
